(19) United States
(12) Patent Application Publication
(10) Pub. No.: US 2009/0296515 A1
(43) Pub. Date: Dec. 3, 2009

(54) FLUID MIXING APPARATUS, INTEGRATED FLUID MIXING APPARATUS, AND FLUID MIXING SYSTEM

(76) Inventors: Takahiro Ezaki, Kanagawa-ken (JP); Susumu Yasuda, Ibaraki-ken (JP); Mamoru Tsukada, Kanagawa-ken (JP); Takayuki Teshima, Kanagawa-ken (JP); Kazumichi Nakahama, Tokyo (JP); Chienliu Chang, Kanagawa-ken (JP)

Correspondence Address: MORGAN & FINNEGAN Transition Team;C/O Locke Lord Bissell & Liddell, 3 WORLD FINANCIAL CENTER, NEW YORK, NY, 10281-2101, US

(21) Appl. No.: 11/722,938

(22) PCT Filed: Dec. 27, 2006
(86) PCT No.: PCT/JP2006/326372

§ 371 Date: Apr. 6, 2009

(30) Foreign Application Priority Data
Dec. 28, 2005 (JP) 2005-378701

(51) Int. Cl. B01F 15/02; B01F 15/06; H01L 21/306

(52) U.S. Cl. 366/132; 366/134; 438/689; 257/E21.215

(57) ABSTRACT

A fluid mixing apparatus is constituted by a plurality of flow passageways for conveying fluids, respectively, and jet outlets, corresponding to and communicating with the flow passageways, respectively, for jetting the fluids therefrom so that movement directions of the fluids intersect each other to mix the fluids. The jet outlets are provided at a surface of a substrate in which the flow passageways are provided. At least one of the flow passageways communicating with at least one of the jet outlets has a center axis partially shifted from a center axis of at least one of the jet outlets so as to incline a movement direction of a fluid jetted from at least one of the jet outlets with respect to the surface of the substrate.

### TECHNICAL FIELD

The present invention relates to a fluid mixing apparatus for jetting fluids and mixing the fluids each other, an integrated fluid mixing apparatus including the fluid mixing apparatus, and fluid mixing system using the integrated fluid mixing apparatus.

### BACKGROUND ART

In recent years, in the fields of chemical industries including production of pigments or the like used in an ink jet printer and pharmaceutical industries including production of medical and pharmaceutical products, regards, etc., development of a new production process using a minute vessel using a minute vessel which is called a micromixer or a microreactor has been advanced. In a conventional batch type reaction apparatus, a primary product successively causes reaction in the apparatus, so that nonuniformity of a reaction product is caused to occur in some cases. Particularly, in the case where fine particles are produced, primary particles of fine particles once provided further grow by the reaction, so that there is a possibility of an occurrence of nonuniformity in particle size of the fine particles.

On the other hand, in the micromixer, fluids continuously flow in microscale flow passageways with almost no retention, so that it is possible to prevent the once produced fine particles from reacting again, thereby to enhance particle size uniformity of the fine particles.

Incidentally, the micromixer and the microreactor have a common basic structure but in some cases, a mixing apparatus with chemical reaction during mixing of a plurality of solutions is particularly referred to as a microreactor. In the following description, the micromixer and the microreactor are inclusively referred to as the micromixer.

As a method using such a micromixer, Japanese Laid-Open Patent Application (JP-A) No. 2002-336667 has disclosed a method in which two fluids are mixed at high speed to produce a solid precipitate. More specifically, as shown in FIG. 15, in this method, the two fluids are supplied to orifices 101 and 102 to pass through tapered portions, thus producing a solid precipitate in a jet impingement mixing chamber 104.

Further, a metal-made micromixer having oblique nozzles formed by mechanical processing as shown in FIG. 16, such as “Impinging Jet Micro Mixer”, mfd. by Institut fur Mikrotechnik Mainz GmbH. This is a micromixer for jetting fluids from two nozzles 105 and 106 so as to mix the fluids in the air.

Further, JP-A No. Hei 9-1808 has disclosed an ink jet head used in an ink jet recording apparatus. This head includes two flow passageways shifted and connected at a connecting portion provided with a heat generation member and ink is introduced from one flow passageway and, after being caused to generate bubbles, ejected from the other flow passageway. An ink ejection direction from the head is perpendicular to a surface of a substrate. From the head, single ink is ejected. Thus, JP-A No. Hei 9-1808 is silent about mixing of two or more fluids.

When the micromixer as described above is used, compared with the batch type reaction apparatus using a large volume tank or the like, a site of mixing and reaction is smaller, so that it is possible to produce fine particles having a narrow particle size distribution.

However, in order to realize a smaller and further uniform particle size in the methods described above, it is required that a mixing efficiency is further improved. For this purpose, a nozzle is required to be reduced in diameter to decrease an absolute amount of fluid. Further, in order to increase productivity of a mixer, it is required that a large number of nozzles are prepared. However, in an ordinary mechanical processing method, there is a limit to a small-size nozzle. In the case of preparing the large number of nozzles, the mechanical processing or laser processing takes much time, thus leading to an increase in production cost. Further, it is difficult to ensure positions or sizes of the nozzles with high accuracy. Moreover, in the ordinary mechanical processing, shapes of holes of the nozzles have been limited to a circle.

By using photolithography and dry etching of silicon, it is possible to simultaneously prepare several thousand nozzles having a diameter of several tens of μm at a high positional accuracy. In this case, however, the etching is generally performed in a direction perpendicular to a substrate, so that it has been difficult to prepare nozzles for obliquely jetting fluid.

### DISCLOSURE OF THE INVENTION

A principal object of the present invention is to provide a fluid mixing apparatus capable of obtaining fine particles having a small and uniform particle size.

Another object of the present invention is to provide a fluid mixing apparatus capable of mixing a plurality of fluids so as to obtain a solid product through reaction of the plurality of fluids.

A further object of the present invention is to provide an integrated fluid mixing apparatus using the fluid mixing apparatus.

A still further object of the present invention is to provide a fluid mixing system capable of meeting a necessary amount of production by appropriately disposing a necessary number of fluid mixing apparatuses or integrated fluid mixing apparatuses.

According to an aspect of the present invention, there is provided a fluid mixing apparatus comprising:

a plurality of flow passageways for conveying fluids, respectively; and

jet outlets, corresponding to and communicating with the flow passageways, respectively, for jetting the fluids therefrom so that movement directions of the fluids intersect each other to mix the fluids,

wherein the jet outlets are provided at a surface of a substrate in which the flow passageways are provided, and wherein at least one of the flow passageways communicating with at least one of the jet outlets has a center axis partially shifted from a center axis of at least one of the jet outlets so as to incline a movement direction of a fluid jetted from at least one of the jet outlets with respect to the surface of the substrate.

According to another aspect of the present invention, there is provided an integrated fluid mixing apparatus, wherein the fluid mixing apparatus includes a plurality of supply flow passageways for supplying fluids to a plurality of flow passageways and includes a plurality of first jet outlets for jetting a first fluid and a plurality of second jet outlets, corresponding to the plurality of first jet outlets, for jetting a second fluid. In the integrated fluid mixing apparatus, the first fluid is supplied to the plurality of first jet outlets through a first supply flow passageway, and the second fluid is supplied to the plurality of second jet outlets through a second supply flow passageway.

According to a further aspect of the present invention, there is provided a fluid mixing system comprising:

a fluid mixing apparatus according to claim 12;

supply fluid retaining means for retaining fluid to be supplied to the fluid mixing apparatus;

first temperature control means for controlling a temperature of the fluid to be supplied to the fluid mixing apparatus;

conveying means for conveying the fluid from the supply fluid retaining means to the fluid mixing apparatus;

fluid control means for controlling the conveying means;

second temperature control means for controlling a temperature of the fluid flowing out of the fluid mixing apparatus; and

flow-out fluid retaining means for retaining the fluid flowing out of the fluid mixing apparatus.

According to a still further aspect of the present invention, there is provided a process for producing a fluid mixing apparatus including a substrate and at least two fluid jetting means provided to the substrate so that at least two the fluid jetting means are disposed to jet fluids in directions intersecting each other so as to mix the fluids, the process comprising:

a step of forming a first flow passageway by effecting etching from a first surface of the substrate; and

a step of obtaining fluid jetting means by forming a second flow passageway through etching from a second surface of the substrate opposite from the first surface so that the first flow passageway and the second flow passageway have center axes shifted from each other and connecting the first flow passageway and the second flow passageway to each other at their side portions located between their center axes.

These and other objects, features and advantages of the present invention will become more apparent upon a consideration of the following description of the preferred embodiments of the present invention taken in conjunction with the accompanying drawings.

### BRIEF DESCRIPTION OF THE DRAWINGS

FIGS. 1(a) and 1(b) are schematic views for illustrating an embodiment of a fluid jetting means used in the fluid mixing apparatus according to the present invention.

FIG. 2 is a schematic view for illustrating another embodiment of a fluid jetting means used in the fluid mixing apparatus of the present invention.

FIGS. 3 and 4 are schematic views for illustrating a fluid mixing apparatus used in Embodiment 1.

FIGS. 5(a) and 5(b) are schematic views for illustrating a fluid mixing apparatus used in Embodiment 3.

FIG. 6 is a schematic sectional view for illustrating a fluid mixing apparatus used in Embodiment 5.

FIGS. 7(a) and 7(b) are schematic views for illustrating an integrated fluid mixing apparatus used in Embodiment 6.

FIGS. 8A and 8B are schematic sectional views for illustrating a production process of the integrated fluid mixing apparatus used in Embodiment 6.

FIGS. 9(a) and 9(b) are schematic views for illustrating an integrated fluid mixing apparatus used in Embodiment 8.

FIGS. 10A and 10E are schematic views for illustrating an integrated fluid mixing apparatus used in Embodiment 9.

FIG. 11 is a schematic view for illustrating a fluid mixing system used in Embodiment 10.

FIGS. 12(a) and 12(b) are schematic views for illustrating a fluid mixing apparatus used in Embodiment 2.

FIGS. 13(a), 13(b) and 13(c) are schematic views for illustrating a fluid mixing apparatus used in Embodiment 4.

FIGS. 14(a) and 14(b) are schematic views for illustrating an integrated fluid mixing apparatus used in Embodiment 7.

FIGS. 15 and 16 are schematic views for illustrating conventional micromixers.

### BEST MODE FOR CARRYING OUT THE INVENTION

Hereinbelow, the present invention will be described in detail.

A fluid mixing apparatus according to the plurality of includes a plurality of flow passageways for conveying fluids, respectively; and jet outlets, corresponding to and communicating with the flow passageways, respectively, for jetting the fluids therefrom so that movement directions of the fluids intersect each other to mix the fluids, wherein the jet outlets are provided at a surface of a substrate in which the flow passageways are provided, and wherein at least one of the flow passageways communicating with at least one of the jet outlets has a center axis partially shifted from a center axis of at least one of the jet outlets so as to incline a movement direction of a fluid jetted from at least one of the jet outlets with respect to the surface of the substrate.

At least one of the flow passageways may comprise a first flow passageway and a second flow passageway which are parallel to each other and through which an associated fluid passes to reach an associated jet outlet, and wherein the first flow passageway and the second flow passageway may be connected to each other at their side portions located between their center axes.

Between adjacent jet outlets of the jet outlets, a recess may be provided. Further, between adjacent jet outlets of the jet outlets, a plurality of recesses may be provided. Each of the jet outlets may be surrounded by a peripheral portion which has been subjected to water-repellent treatment or oil-repellent treatment. The substrate may comprise a silicon-containing material and the flow passageways are formed by a semiconductor fine processing. The substrate may be a lamination structure comprising layers of silicon, an oxide, silicon, an oxide, and silicon. The first flow passageway and the second flow passageway may preferably have chemical resistance. Each of movement directions of two fluids jetted from two jet outlets may be inclined with respect to the surface of the substrate to mix the two fluids. One of the flow passageways communicating with an associated jet outlet may be a linear flow passageway through which a fluid is jetted in a direction perpendicular to the surface of the substrate.

The fluid mixing apparatus may further comprise supply flow passageways for supplying the fluids to the flow passageways. The fluid mixing apparatus may be configured to mix at least two fluids and may comprise a plurality of first jet outlets for jetting a first fluid and a plurality of second jet outlets, corresponding to the plurality of first jet outlets, for jetting a second fluid, and wherein the first fluid may be supplied to the plurality of first jet outlets through a first supply flow passageway, and the second fluid may be supplied to the plurality of second jet outlets through a second supply flow passageway. The fluid mixing apparatus may further comprise a supply plate provided with the first supply flow passageway and the second supply flow passageway and the substrate may be provided with the first jet outlets and the second jet outlets. In this case, the substrate and the supply plate may be connected to each other.

A process for producing a fluid mixing apparatus including a substrate and at least two fluid jetting means provided to the substrate so that at least two the fluid jetting means are disposed to jet fluids in directions intersecting each other so as to mix the fluid according to the present invention includes: a step of forming a first flow passageway by effecting etching from a first surface of the substrate; and a step of obtaining fluid jetting means by forming a second flow passageway through etching from a second surface of the substrate opposite from the first surface so that the first flow passageway and the second flow passageway have center axes shifted from each other and connecting the first flow passageway and the second flow passageway to each other at their side portions located between their center axes.

According to the present invention, by using a conventional semiconductor production technique including a combination of photolithography and etching, minute fluid jetting means is formed on a substrate to jet the fluid at a specific angle with respect to a surface of the substrate. As a result, a size of the jet outlets (also referred to as “nozzle(s)” for jetting the fluid can be reduced, so that it is possible to realize an integrated fluid mixing apparatus using the fluid jetting means constituted by the plurality of nozzles at high positional accuracy. Further, in the case of preparing a large number of nozzles, a processing time can be reduced compared with a conventional ordinary machine processing, so that a production cost can be reduced. Further, the shape of holes of nozzles as the fluid jetting means is not limited to a circular shape.

Conventionally, in order to produce a large amount of a mixture substance, by a large-scale production facility, which has been produced through a laboratory-scale production facility, plant design is newly required. For this reason, in order to ensure a reaction reproducibility, much effort and time have been expended. When the fluid mixing system of the present invention is used, the effort and time can be considerably reduced since a necessary production amount can be met by integration of the fluid mixing apparatus.

Next, the fluid jetting means used in the fluid mixing apparatus will be described.

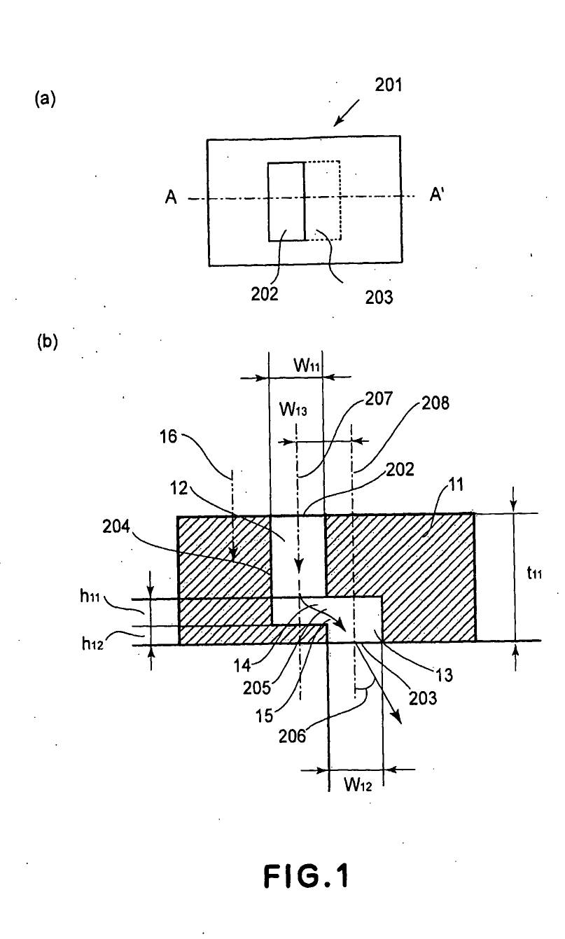

FIGS. 1(a) and 1(b) are schematic views showing an embodiment of the fluid jetting means used in the fluid mixing apparatus of the present invention, wherein FIG. 1(a) is a plan view and FIG. 1(b) is a sectional view taken along A-A′ line. The fluid jetting means shown in these figures is inclined fluid jetting means.

The fluid mixing apparatus include a substrate 11 and at least two fluid jetting means 201, provided to the substrate 11, for jetting fluids. These (at least two) fluid jetting means 201 are disposed so that jetting directions of the fluids intersect each other to mix the fluids.

As shown in FIGS. 1(a) and 1(b), the fluid jetting means 201 includes a first flow passageway 12 and a second flow passageway 13 which are parallel to each other. A side portion 14 of one end portion of the first flow passageway 12 and a side portion 15 of one end portion of the second flow passageway 13 are opened and connected to each other. A center axis of the first flow passageway 12 and that of the second flow passageway 13 are shifted from each other. The first flow passageway 12 has an inlet port 202 at the other end portion from which the fluid is introduced. The second flow passageway 13 has a jet outlet 203 from which the introduced fluid is jetted in a direction inclined with respect to a parallel direction 16 to the flow passageways 12 and 13. The fluid jetting means 201 is referred to as an inclined fluid jetting means since the fluid is jetted in an inclined or oblique direction with respect to the parallel direction 16.

The fluid jetting means 201 includes a flow passageway 204 constituted by the first flow passageway 12 and second flow passageway 13 which penetrate through the substrate 11 in combination as described above. At a connecting portion 205 of the flow passageway 204, the first flow passageway 12 having the inlet port 202 and the second flow passageway 13 having the jet outlet 203 are connected to each other. Further, the flow passageway 204 is constituted so that an axis 207 passing through a center of a cross section of the inlet port 202 and an axis 208 passing through a center of a cross section of the jet outlet 203 are not aligned with each other. By introducing the fluid through the inlet port 202 at a specific pressure, the fluid is jetted from the jet outlet 203 at a specific angle 206 with respect to a direction perpendicular to the substrate surface.

The connecting portion 205 of the flow passageway 204 has a length or distance w13 between the center axis 207 of the cross section of the inlet port 202 and the center axis 208 of the cross section of the jet outlet 203.

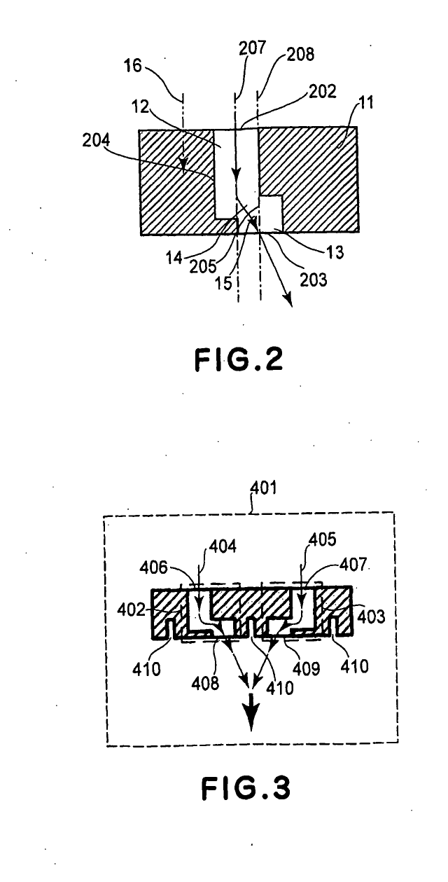

FIG. 2 is a schematic sectional view showing another embodiment of the fluid jetting means used in the fluid mixing apparatus of the present invention. A connecting portion 205 shown in FIG. 2 has a length shorter than that of the connecting portion 205 shown in FIG. 1(b). More specifically, FIG. 2 shows such a fluid jetting means that a distance between an axis 207 passing through a center of a cross section of an inlet port 202 of a flow passageway 204 and an axis 208 passing through a center of a cross section of a jet outlet 203 of the flow passageway 204 is shorter.

With respect to a jetting state, a simulation is performed by computation of numerical fluid flow. A calculation result will be described with reference to FIG. 1(b).

Calculation is performed by changing a height h12 from the jet outlet 203 to the end of connecting portion 205 to 10 μm, 25 μm, and 50 μm on assumptions that fluid is water, the substrate 11 has a thickness t11 of 200 μm, the inlet port 202 has a width w11 of 100 μm, the jet outlet 203 has a width w12 of 100 μm, and the connecting portion 205 has a height h11 of 50 μm.

As a result, a maximum jet angle 206 is about 48 degrees when h12 is 10 μm, about 35 degrees when h12 is 25 μm, and about 18 degrees when h12 is 50 μm. In any of these cases, it has been found that the jet angle is stabilized when a flow rate exceeds 20 m/s. The fluid mixing apparatus may desirably be driven at a flow rate not less than a flow rate at which the jet angle is stabilized.

The respective portions of the fluid jetting means may preferably be designed as shown below.

The inlet port may appropriately have the width w11 of 10 μm or more and 1000 μm or less, preferably 10 μm or more and 500 μm or less, particularly preferably 100 μm or more and 500 μm or less.

The jet outlet may appropriately have the width w12 of 1 μm or more and 500 μm or less, preferably 1 μm or more and 250 μm or less, particularly preferably 1 μm or more and 200 μm or less.

The connecting portion may appropriately have the height h11 of 10 μm or more and 200 μm or less, preferably 10 μm or more and 100 μm or less, particularly preferably 40 μm or more and 80 μm or less.

The connecting portion may appropriately have the length of 5 μm or more and 100 μm or less, preferably 10 μm or more and 800 μm or less, particularly preferably 50 μm or more and 600 μm or less.

The height h12 from the jet outlet to the end of the connecting portion may appropriately be 5 μm or more and 100 μm or less, preferably 10 μm or more and 100 μm or less, particularly preferably 10 μm or more and 50 μm or less.

The flow rate of the fluid may appropriately be at least 1 m/s, preferably 1 m/s or more and 100 m/s or less.

The fluid may be preferably introduced at a pressure of 1 kPa or more. In this case, the fluid is capable of being jetted in the above described flow rate range.

The jet angle 206 may appropriately be 10 degrees or more and 80 degrees or less, preferably 10 degrees or more and 60 degrees or less, particularly preferably 20 degrees or more and 45 degrees or less.

In order to produce a pigment, it is preferable that the inlet port width w11 is 100 μm or more and 500 μm or less, the jet outlet width w12 is 1 μm or more and 200 μm or less, the connecting portion height h11 is 40 μm or more and 80 μm or less, and the height h12 from the jet outlet to the end of the connecting portion is 10 μm or more and 50 μm or less.

The fluid used in the present invention can be used irrespective of a value of viscosity thereof. However, as the fluid viscosity is higher, pressure loss during the passing of the fluid through the jet outlet is generally larger. Accordingly, in the case where the fluid to be jetted is high, it is desirable that the flow passageway 204 has a large cross-sectional area and the connecting portion 205 has a larger area.

Further, with respect to the fluid jetting means in the present invention, the cross-sectional shape of the jet outlet is not particularly limited but may also be a polygonal shape, a circular shape, a semicircular shape, or an elliptical shape. Further, the cross-sectional shape of the flow passageway is not particularly limited but may also be a polygonal shape, a circular shape, a semi-circular shape, or an elliptic shape.

Incidentally, in the case where the cross-sectional shape of the jet outlet is the circular shape or the elliptical shape, an overlapping area of the side portions 14 and 15 of the end portions of the first and second flow passageways 12 and 13 may preferably be 1/10 or more and ½ or less of a cross-sectional area of the jet outlet. The connecting portion may preferably have a rectangular shape.

### EMBODIMENTS

Hereinbelow, the present invention will be described more specifically based on Embodiments. In the following Embodiments, dimensions, shapes, materials, and production processes are just a few examples of those usable in the present invention.

### Embodiment 1

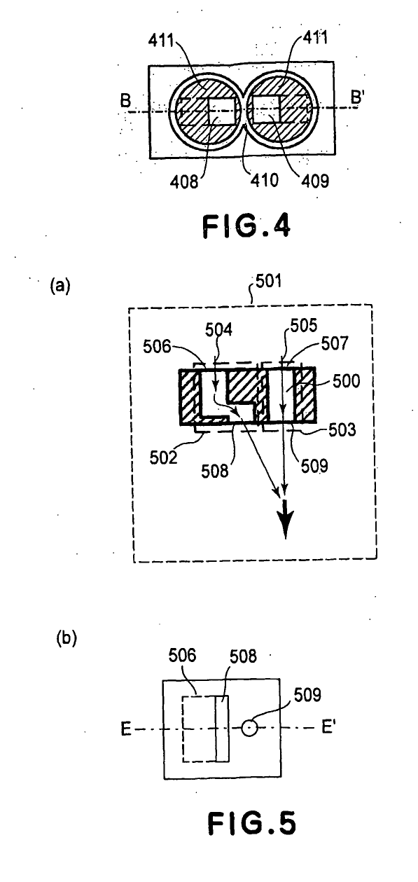

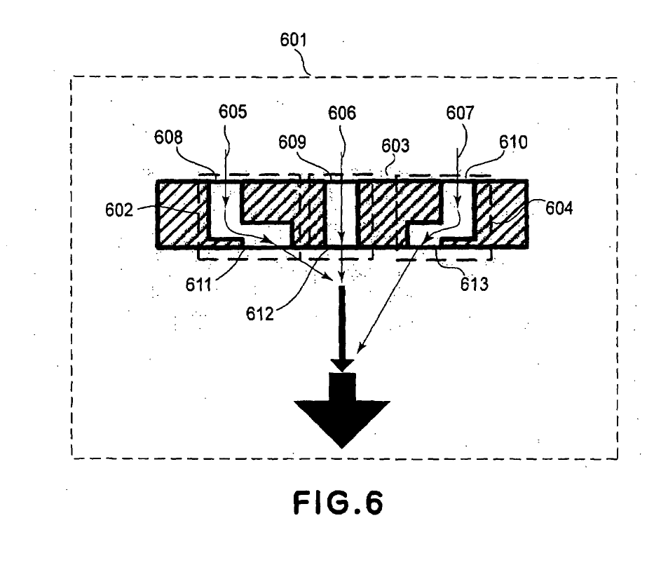

FIGS. 3 and 4 are schematic views for illustrating a fluid mixing apparatus according to Embodiment 1 of the present invention, wherein FIG. 3 is a sectional view of the fluid mixing apparatus and FIG. 4 is a plan view observed from a jet outlet side shown in FIG. 3. FIG. 3 is the sectional view taken along B-B′ line shown in FIG. 4.

A fluid mixing apparatus 401 includes a substrate provided with fluid jetting means 402 and 403 which are disposed with mutually intersecting jet directions and are inclined fluid jetting means.

A manner of mixing Figures in the fluid mixing apparatus will be described with reference to FIGS. 3 and 4. A first fluid 404 is introduced from an inlet port 406 at a specific pressure and jetted from a jet outlet 408 at a specific angle with respect to a surface of a substrate. Similarly, a second fluid 405 is introduced from an inlet port 407 at a specific pressure and jetted from a jet outlet 409 at a specific angle with respect to the surface of the substrate. The jetted first and second fluids 404 and 405 intersect each other at a lower portion of the fluid mixing apparatus 401 to be mixed.

Further, as shown in FIG. 4, between the fluid jetting means 402 and 403, a recess 410 may desirably be provided. As a result, it is possible to prevent the first fluid 404 adhered to a peripheral portion of the jet outlet 408 from flowing into the jet outlet 409. Similarly, it is possible to prevent the second fluid 405 adhered to a peripheral portion of the jet outlet 409 from flowing into the jet outlet 408. Further, the recess 410 between the fluid jetting means 402 and 403 may desirably be disposed to surround those fluid jetting means 402 and 403. This is because the first fluid 404 adhered to the peripheral portion of the jet outlet 408 is prevented from flowing in another direction. However, in the present invention, the recess 410 is not an essential constituent.

Further, referring to FIG. 4, peripheral portions 411 of the jet outlets 408 and 409 may desirably be subjected to water/oil repellent treatment. As a result, a jet angle of fluid can be stabilized. For example, it is also possible to form a layer of a resin material having a water/oil repellent performance by a spin coater and then effect patterning only in a necessary area.

The fluid mixing apparatus according to this embodiment is particularly effective in reaction such that a solid product is formed by reaction caused through mixing of the fluids. This is because the solid product is formed by the reaction caused outside the flow passageways, so that the insides of the flow passageways are not clogged.

### Embodiment 2

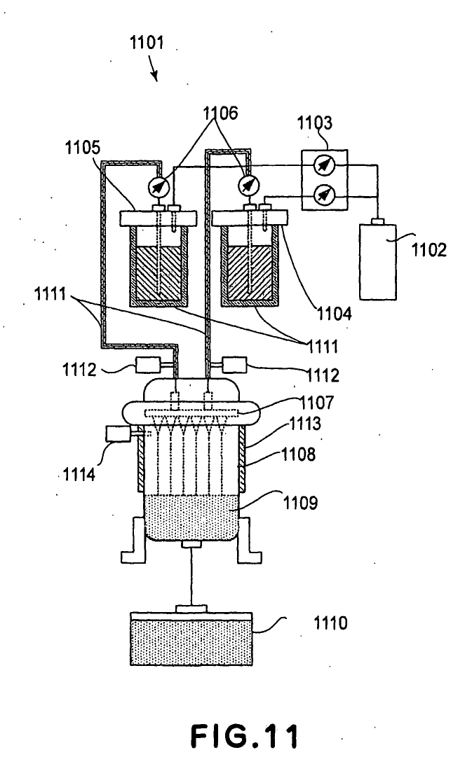

FIGS. 12(a) and 12(b) are schematic views for illustrating a fluid mixing apparatus according to Embodiment 2 of the present invention, wherein FIG. 12(a) is a sectional view of the fluid mixing apparatus and FIG. 12(b) is a plan view observed from a jet outlet side shown in FIG. 12(a). FIG. 12(a) is the sectional view taken along F-F′ line shown in FIG. 12(b).

A fluid mixing apparatus 1201 includes a substrate provided with fluid jetting means 1202 and 1203 which are disposed with mutually intersecting jet directions and are inclined fluid jetting means.

A manner of mixing Figures in the fluid mixing apparatus will be described with reference to FIG. 12(a). A first fluid 1204 is introduced from an inlet port 1206 at a specific pressure and jetted from a jet outlet 1208 at a specific angle with respect to a surface of a substrate. Similarly, a second fluid 1205 is introduced from an inlet port 1207 at a specific pressure and jetted from a jet outlet 1209 at a specific angle with respect to the surface of the substrate. The jetted first and second fluids 1204 and 1205 intersect each other at a lower portion of the fluid mixing apparatus 1201 to be mixed.

Further, as shown in FIG. 12(a), between the fluid jetting means 1202 and 1203, a plurality of recess 1212 may desirably be provided. As a result, it is possible to prevent the first fluid 1204 adhered to a peripheral portion of the jet outlet 1208 from flowing into the jet outlet 1209. Similarly, it is possible to prevent the second fluid 1205 adhered to a peripheral portion of the jet outlet 1209 from flowing into the jet outlet 1208. Further, the plurality of recess 1212 between the fluid jetting means 1202 and 1203 may desirably be disposed to surround those fluid jetting means 1202 and 1203. As a result, the first fluid 1204 adhered to the peripheral portion of the jet outlet 1208 is prevented from flowing in another direction. Similarly, the second fluid 1205 adhered to the peripheral portion of the jet outlet 1209 is prevented from flowing in another direction. However, in the present invention, the recesses 1212 are not an essential constituent.

Further, referring to FIG. 12(b), peripheral portions 1213 of the jet outlets 1208 and 1209 may desirably be subjected to water/oil repellent treatment. As a result, a jet angle of fluid can be stabilized. For example, it is also possible to form a layer of a resin material having a water/oil repellent performance by a spin coater and then effect patterning only in a necessary area.

The fluid mixing apparatus according to this embodiment is particularly effective in reaction such that a solid product is formed by reaction caused through mixing of the fluids. This is because the solid product is formed by the reaction similarly as in Embodiment 1.

### Embodiment 3

### Fluid Mixing Apparatus Including Fluid Jetting Means and Linear Fluid Jetting Means

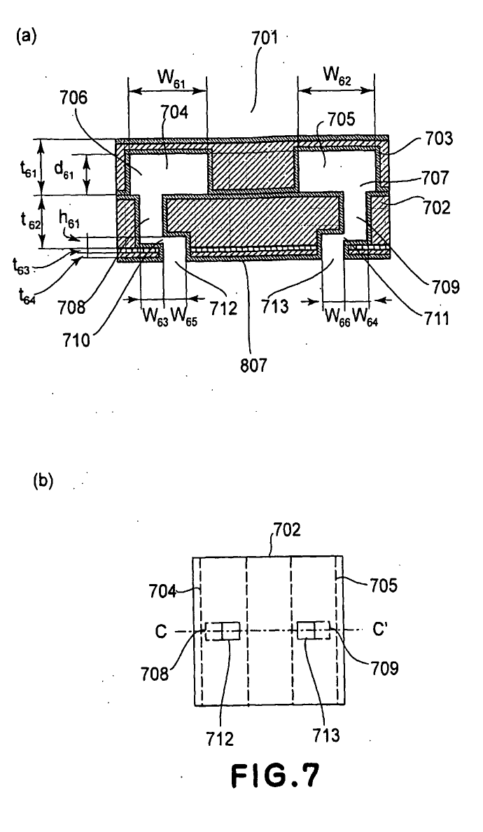

FIGS. 5(a) and 5(b) are schematic views for illustrating a fluid mixing apparatus according to Embodiment 3 of the present invention, wherein FIG. 5(a) is a sectional view of the fluid mixing apparatus and FIG. 5(b) is a plan view observed from a jet outlet side shown in FIG. 5(a). FIG. 5(a) is the sectional view taken along E-E′ line shown in FIG. 5(b).

A fluid mixing apparatus 501 includes inclined fluid jetting means 502 and linear fluid jetting means 503 including a linear (straight) flow passageway 500 for jetting a fluid in a linear direction. These fluid jetting means 502 and 503 are disposed with mutually intersecting jet directions.

A manner of mixing Figures in the fluid mixing apparatus will be described with reference to FIG. 5(a). A first fluid 504 is introduced from an inlet port 506 at a specific pressure and jetted from a jet outlet 508 at a specific angle with respect to a surface of a substrate. Similarly, a second fluid 505 is introduced from an inlet port 507 at a specific pressure and jetted from a jet outlet 509 in a direction perpendicular to the surface of the substrate. The jetted first and second fluids 504 and 505 intersect each other at a lower portion of the fluid mixing apparatus 501 to be mixed.

As shown in FIG. 5(b), the jet outlet 508 has a rectangular shape and the jet outlet 509 has a circular shape. As a result, even when the jet direction of the second fluid 505 is changed, the first fluid 504 is jetted in a band-like shape, so that they are always caused to impinge against each other. Further, by disposing a plurality of jet outlets 509 along a long side direction, it is possible to change a mixing ratio between the first fluid 504 and the second fluid 505. Incidentally, the combination of the shapes of the first and second jet outlets is not limited to the above described combination but may also be a combination of circular shapes different in diameter or a combination of a rectangular shape and a rectangular shape.

It is desirable that peripheral portions of the jet outlets 508 and 509 have been subjected to water/oil repellent treatment. As a result, a fluid jet angle is stabilized. Further, the water/oil repellent treatment for the jet outlets 508 and 509 is not necessarily required.

Further, between the fluid jetting means 502 and 503, a recess may desirably be provided. As a result, it is possible to prevent the first fluid 504 adhered to a peripheral portion of the jet outlet 508 from flowing into the jet outlet 509. Similarly, it is possible to prevent the second fluid 505 adhered to a peripheral portion of the jet outlet 509 from flowing into the jet outlet 508. Further, the provision of the recess between the fluid jetting means 502 and 503 is not necessarily required.

Further, between the fluid jetting means 502 and 503, a plurality of recesses may desirably be provided. As a result, it is possible to prevent the first fluid 504 adhered to a peripheral portion of the jet outlet 508 from flowing into the jet outlet 509. Similarly, it is possible to prevent the second fluid 505 adhered to a peripheral portion of the jet outlet 509 from flowing into the jet outlet 508. Further, the plurality of recesses between the fluid jetting means 502 and 503 may desirably be disposed to surround those fluid jetting means 502 and 503. As a result, the first fluid 504 adhered to the peripheral portion of the jet outlet 508 is prevented from flowing in another direction. Similarly, the second fluid 505 adhered to the peripheral portion of the jet outlet 509 is prevented from flowing in another direction. Further, the provision of the plurality of recesses between the fluid jetting means 502 and 503 is not necessary required.

The first fluid 504 may desirably have a surface tension larger than that of the second fluid 505. Even when the water/oil repellent treatment is effected at the jet outlet peripheral portions, a fluid having a small surface tension is liable to wet at the jet outlet peripheral portions. For this reason, there is a possibility that a jet angle of fluid when the fluid is jetted in an inclined direction with respect to the substrate surface is unstable, so that the fluid can flow into the other (distant) jet outlet. In this embodiment, the (second) fluid having the smaller surface tension can be jetted in a direction perpendicular to the substrate surface, so that it is possible to prevent the fluid from flowing into the other (distant) jet outlet. The jetting of the fluid having the smaller surface tension in the direction perpendicular to the substrate surface is not necessarily required.

The fluid mixing apparatus according to this embodiment is particularly effective in reaction such that a solid product is formed by reaction similarly as in Embodiment 1.

### Embodiment 4

### Fluid Mixing Apparatus Including Fluid Jetting Means with Arc-Shaped Jet Outlet

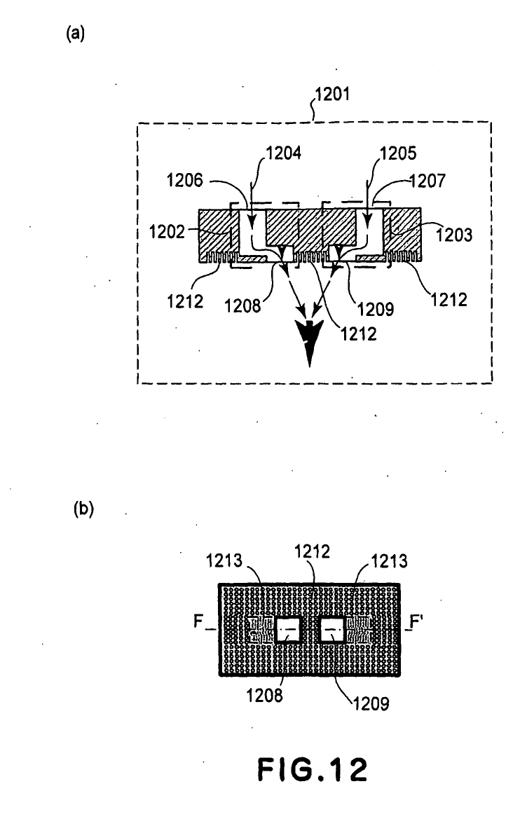

FIGS. 13(a), 13(b) and 13(c) are schematic views for illustrating a fluid mixing apparatus according to Embodiment 4 of the present invention, wherein FIGS. 13(a) and 13(b) are sectional views of the fluid mixing apparatus and FIG. 13(c) is a plan view observed from a jet outlet side shown in FIGS. 13(a) and 13(b). FIG. 13(a) is the sectional view taken along G-G′ line shown in FIG. 13(c). FIG. 13(b) is the sectional view taken along H-H′ line shown in FIG. 13(c).

A fluid mixing apparatus 1301 includes inclined fluid jetting means 1302 having an arc-shaped jet outlet 1311 and linear fluid jetting means 1303 including a flow passageway vertically penetrating through a substrate. These fluid jetting means 1302 and 1303 are disposed with mutually intersecting jet directions at one position.

A manner of mixing Figures in the fluid mixing apparatus will be described with reference to FIG. 13(a). A first fluid 1305 is introduced from an inlet port 1308 at a specific pressure and jetted from a jet outlet 1311 at a specific angle with respect to a surface of a substrate. Similarly, a second fluid 1306 is introduced from an inlet port 1309 at a specific pressure and jetted from a jet outlet 1312 in a direction perpendicular to the surface of the substrate. At this time, the first fluid 1305 is jetted in an arc-like shape and a band-like shape. The jetted first and second fluids 1305 and 1306 intersect each other at a lower portion of the fluid mixing apparatus 1301 to be mixed.

It is desirable that peripheral portions of the jet outlets 1311 and 1312 have been subjected to water/oil repellent treatment. As a result, a fluid jet angle is stabilized. Further, the water/oil repellent treatment for the jet outlets 1311 and 1312 is not necessarily required.

Further, between the fluid jetting means 1302 and 1303, a recess may desirably be provided. As a result, it is possible to prevent the first fluid 1305 adhered to a peripheral portion of the jet outlet 1311 from flowing into the jet outlet 1312. Similarly, it is possible to prevent the second fluid 1306 adhered to a peripheral portion of the jet outlet 1312 from flowing into the jet outlet 1311. Further, the provision of the recess between the fluid jetting means 1302 and 1303 is not necessarily required.

Further, between the fluid jetting means 1302 and 1303, a plurality of recesses may desirably be provided. As a result, it is possible to prevent the first fluid 1305 adhered to a peripheral portion of the jet outlet 1311 from flowing into the jet outlet 1312. Similarly, it is possible to prevent the second fluid 1306 adhered to a peripheral portion of the jet outlet 1312 from flowing into the jet outlet 1311. Further, the plurality of recesses between the fluid jetting means 1302 and 1303 may desirably be disposed to surround those fluid jetting means 1302 and 1303. As a result, the first fluid 1305 adhered to the peripheral portion of the jet outlet 1311 is prevented from flowing in another direction. Similarly, the second fluid 1306 adhered to the peripheral portion of the jet outlet 1312 is prevented from flowing in another direction. Further, the provision of the plurality of recesses between the fluid jetting means 1302 and 1303 is not necessary required.

The first fluid 1305 may desirably have a surface tension larger than that of the second fluid 1306. Even when the water/oil repellent treatment is effected at the jet outlet peripheral portions, a fluid having a small surface tension is liable to wet at the jet outlet peripheral portions. For this reason, there is a possibility that a jet angle of fluid when the fluid is jetted in an inclined direction with respect to the substrate surface is unstable, so that the fluid can flow into the other (distant) jet outlet. In this embodiment, the (second) fluid having the smaller surface tension can be jetted in a direction perpendicular to the substrate surface, so that it is possible to prevent the fluid from flowing into the other (distant) jet outlet. The jetting of the fluid having the smaller surface tension in the direction perpendicular to the substrate surface is not necessarily required.

In the fluid mixing apparatus of this embodiment, by using the arc-shaped jet outlet 1311 as a jet outlet for the fluid jetting means 1302, it is possible to jet the first fluid 1305 in the arc shape and band-like shape. As a result, even when the jet direction of the second fluid 1306 is changed, the second fluid 1306 is always impinged against the first fluid 1305.

The fluid mixing apparatus according to this embodiment is particularly effective in reaction such that a solid product is formed by reaction similarly as in Embodiment 1.

### Embodiment 5

### Fluid Mixing Apparatus in the Intersecting Jet Directions at Two Positions

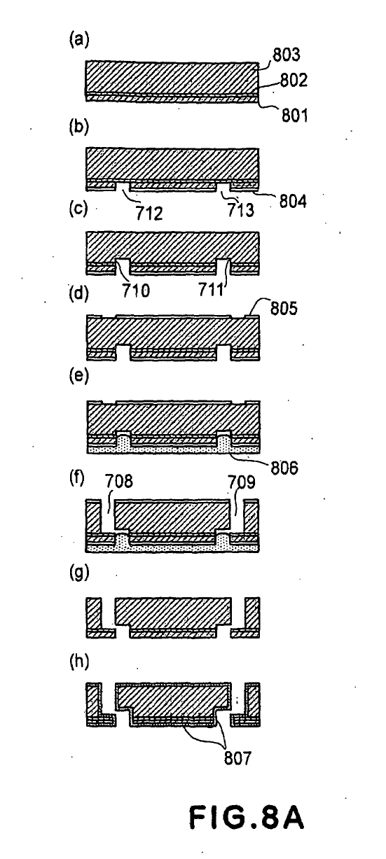

FIG. 6 is a schematic sectional view for illustrating a fluid mixing apparatus according to Embodiment 5 of the present invention.

A fluid mixing apparatus 601 includes inclined fluid jetting means 602 and 604 and linear fluid jetting means 603 including a flow passageway vertically penetrating through a substrate. The fluid jetting means 602 is provided with a jet outlet 611 having a cross-sectional area larger than that of a jet outlet 613. These fluid jetting means 602, 603 and 604 are disposed with mutually intersecting jet directions at two positions.

A manner of mixing Figures in the fluid mixing apparatus will be described with reference to FIG. 6. A first fluid 605 is introduced from an inlet port 608 at a specific pressure and jetted from the jet outlet 611 at a specific angle with respect to a surface of a substrate. Similarly, a second fluid 606 is introduced from an inlet port 609 at a specific pressure and jetted from a jet outlet 612 in a direction perpendicular to the surface of the substrate. Further, a third fluid 607 is introduced from an inlet port 610 at a specific pressure and jetted from the jet outlet 613 at a specific angle with respect to the surface of the substrate. At this time, the jet angle of the third fluid 607 is different from that of the first fluid 605. As a result, the jetted first and second fluids 605 and 606 intersect each other at a lower portion of the fluid mixing apparatus 601 to be mixed, and then intersect with the third fluid 607 to be mixed.

It is desirable that peripheral portions of the jet outlets 611, 612 and 613 have been subjected to water/oil repellent treatment. As a result, a fluid jet angle is stabilized. Further, the water/oil repellent treatment for the jet outlets 611, 612 and 613 is not necessarily required.

Further, between the fluid jetting means 602 and 603 and between the fluid jetting means 603 and 604, a recess may desirably be provided. As a result, it is possible to prevent the first fluid 605 adhered to a peripheral portion of the jet outlet 611 from flowing into the jet outlet 612. Similarly, it is possible to prevent the second fluid 606 adhered to a peripheral portion of the jet outlet 612 from flowing into the jet outlets 611 and 613. Similarly, it is possible to prevent the third fluid 607 adhered to a peripheral portion of the jet outlet 613 from flowing into the jet outlet 612. Further, the provision of the recess between the fluid jetting means 602 and 603 and between the fluid jetting means 603 and 604 is not necessarily required.

Further, between the fluid jetting means 602 and 603 and between the fluid jetting means 603 and 604, a plurality of recesses may desirably be provided. As a result, it is possible to prevent the first fluid 605 adhered to a peripheral portion of the jet outlet 611 from flowing into the jet outlet 612. Similarly, it is possible to prevent the second fluid 606 adhered to a peripheral portion of the jet outlet 612 from flowing into the jet outlets 611 and 613. Similarly, it is possible to prevent the third fluid 607 adhered to a peripheral portion of the jet outlet 613 from flowing into the jet outlet 612. Further, the plurality of recesses between the fluid jetting means 602 and 603 and between the fluid jetting means 603 and 604 may desirably be disposed to surround those fluid jetting means 602 and 603. As a result, the first fluid 605 and second fluid 604 adhered to the peripheral portions of the jet outlets 611 and 613 are prevented from flowing in other directions. Further, the provision of the plurality of recesses between the fluid jetting means 602 and 603 and between the fluid jetting means 603 and 604 is not necessary required.

The first fluid 605 and third fluid 607 may desirably have a surface tension larger than that of the second fluid 606. Even when the water/oil repellent treatment is effected at the jet outlet peripheral portions, a fluid having a small surface tension is liable to wet at the jet outlet peripheral portions. For this reason, there is a possibility that a jet angle of fluid when the fluid is jetted in an inclined direction with respect to the substrate surface is unstable, so that the fluid can flow into the other (distant) jet outlet. In this embodiment, the (second) fluid having the smaller surface tension can be jetted in a direction perpendicular to the substrate surface, so that it is possible to prevent the fluid from flowing into the other (distant) jet outlet. The jetting of the fluid having the smaller surface tension in the direction perpendicular to the substrate surface is not necessarily required.

In the fluid mixing apparatus of this embodiment, at least three fluid jetting means are disposed so that fluid jet directions intersect at least two positions, thus permitting chemical reactions in a desired order.

Further, in the fluid mixing apparatus of this embodiment, by disposing any number of nozzles, it is possible to realize a fluid mixing apparatus capable of mixing any number of kinds of fluids.

### Embodiment 6

### Integrated Fluid Mixing Apparatus

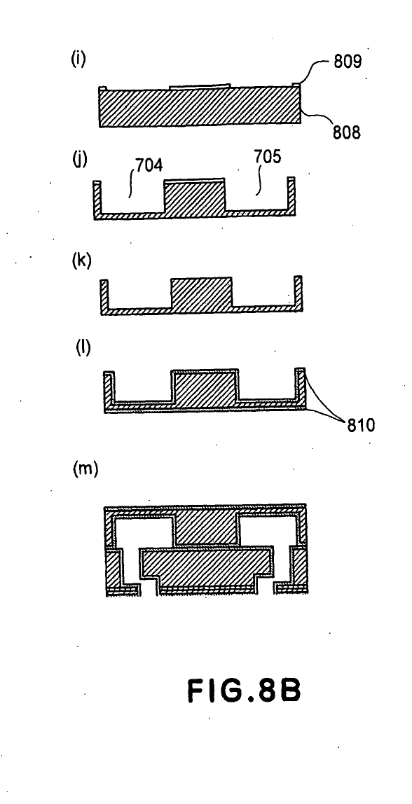

FIGS. 7(a) and 7(b) are schematic views for illustrating an integrated fluid mixing apparatus according to Embodiment 6 of the present invention, wherein FIG. 7(a) is a sectional view of an integrated fluid mixing apparatus 701 and FIG. 7(b) is a plan view observed from a jet outlet side shown in FIG. 7(a). FIG. 7(a) is the sectional view taken along C-C′ line shown in FIG. 7(b).

The integrated fluid mixing apparatus 701 includes a substrate 702 constituting a fluid mixing apparatus according to the present invention and a supply plate 703 provided with supply flow passageways for supplying two kinds of fluid to the fluid mixing apparatus. The substrate 702 and the supply plate 703 are connected to each other.

A manner of mixing fluids in the integrated fluid mixing apparatus will be described with reference to FIG. 7(a). A first reaction liquid (fluid) is introduced from a liquid supply port (not shown) provided to the supply plate 703 to a supply flow passageway 704.

The first reaction liquid passes through the supply flow passageway 704 and an inlet port 706 to be introduced in a flow passageway 708. The fluid (first reaction liquid) passed through the flow passageway 708 is jetted from a jet outlet 712.

A second reaction liquid (fluid) is introduced in a flow passageway 709 through a supply flow passageway 705 and an inlet port 707 and jetted from a jet outlet 713. As a result, the first and second reaction liquids (fluids) jetted from the jet outlets 712 and 713 intersect each other below the substrate 702 to be mixed.

Dimensions of the respective portions will be described. The supply plate 703 has a thickness t61 of 1000 μm. The supply flow passageway 704 has a width w61 of 500 μm, and the supply flow passageway 705 has a width w62 of 500 μm. The supply flow passageways 704 and 705 have a depth d61 of 800 μm.

The substrate 702 is a silicon on insulator (SOI) substrate and includes a silicon layer having a thickness t64 of 25 μm, a silicon oxide film (layer) having a thickness t63 of 0.5 μm, and a support substrate layer having a thickness t62 of 200 μm.

The substrate 702 is provided with the inlet port 706 having a width w63, the inlet port 707 having a width w64, the jet outlet 712 having a width w65, and the jet outlet 713 having a width w66. The widths w63, w64, w65 and w66 are 100 μm. Further, a height h61 of a connecting portion 710 and a height h62 of a connecting portion 711 are 50 μm.

The supply flow passageways 704 and 705 and the flow passageways 708 and 709 are provided (coated) with a silicon nitride film 807 so as to ensure a resistance to an alkaline reaction liquid. Peripheral portions of the jet outlets 712 and 713 may desirably be subjected to a water/oil repellent treatment. By this treatment, a jet angle of fluid can be stabilized. Further, this treatment for the peripheral portions of the jet outlets 712 and 713 is not necessarily required.

In this embodiment, similarly as in Embodiment 1, it is desirable that a recess is provided between the jet outlets 712 and 713. As a result, the first reaction liquid adhered to the peripheral portion of the jet outlet 712 can be prevented from flowing into the jet outlet 713. Similarly, the second reaction liquid adhered to the peripheral portion of the jet outlet 713 can be prevented from flowing into the jet outlet 712. The provision of the recess between the jet outlets 712 and 713 is not necessarily required.

In this embodiment, similarly as in Embodiment 2, it is desirable that a plurality of recesses is provided between the jet outlets 712 and 713. As a result, the first reaction liquid adhered to the peripheral portion of the jet outlet 712 can be prevented from flowing into the jet outlet 713. Similarly, the second reaction liquid adhered to the peripheral portion of the jet outlet 713 can be prevented from flowing into the jet outlet 712. The provision of the plurality of recesses between the jet outlets 712 and 713 is not necessarily required.

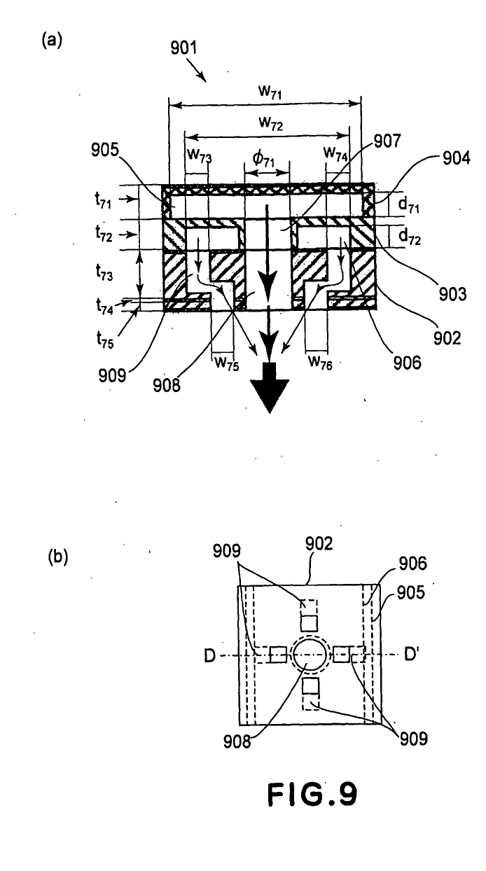

Next, a production process of the integrated fluid mixing apparatus of this embodiment will be described with reference to FIGS. 8A and 8B including sectional views (a) to (h) for illustrating production steps of the substrate 702 and sectional views (i) to (m) for illustrating production steps of the supply plate 703.

An SOI 702 used includes a 25 μm-thick active layer 801, a 0.5 μm-thick silicon oxide film (layer) 802, and a 200 μm-thick support substrate layer 803 (FIG. 8A(a)).

On the active layer 801 side, a pattern of jet outlets 712 and 713 is formed with a photoresist 804 by photolithography. Then, by using the photoresist 804 as an etching mask, the SOI substrate 702 is subjected to dry etching using plasma of SF₆ gas and C₄H₈ gas to form the jet outlets 712 and 713 having a depth of 25 μm (FIG. 8A(b)).

The etched portions are further dry-etched by plasma of SF₆ gas and C₄F₈ gas after corresponding portions of the silicon nitride film 802 are removed by buffered hydrogen fluoride (BHF), thus forming connecting portions 710 and 711 having a depth of 50 μm (FIG. 8A(c)).

Next, on the support substrate layer 803 side, a pattern of inlet ports 706 and 707 is formed with a resist 805 (FIG. 8A(d)).

Then, on the active layer 801 side, a 15 μm-thick photoresist 806 is formed in order to protect the pattern of the jet outlets (FIG. 8A(e)).

From the support substrate layer 803 side (opposite from the active layer 801 side (etching surface side)), dry etching is effected by plasma of SF₆ gas and C₄H₈ gas so that etched portions reach the silicon oxide film 802 as an etching stopper to form remaining portions of flow passageways 708 and 709 (FIG. 8A(f)).

After the photoresists are removed by O₂ plasma treatment, the substrate is washed with a mixture solution of sulfuric acid and hydrogen peroxide solution at a solution temperature of 110° C. (FIG. 8A(g)).

Then, a silicon nitride film 807 is formed by low pressure chemical vapor deposition (LPCVD) (FIG. 8A(h)).

Next, the production steps of the supply plate 703 will be described.

First, a silicon substrate 808 is prepared. A pattern of supply flow passageways 704 and 705 is formed with a photoresist 809. By using the photoresist 809 as an etching mask, the silicon substrate 808 is subjected to dry etching by plasma of SF₆ gas and C₄F₈ gas to form the supply flow passageways 704 and 705 having a depth of 800 μm (FIG. 8B(i) and (j)).

Next, after the photoresist 809 is removed by O₂ plasma treatment, the supply plate is washed with a mixture solution of sulfuric acid and hydrogen peroxide solution at a solution temperature of 110° C. (FIG. 8B(k)).

A silicon nitride film 810 is formed by LPCVD (FIG. 8B(l)).

The above prepared substrate 702 and supply plate 703 are directly connected to each other to prepare an integrated fluid mixing apparatus 701 in this embodiment (FIG. 8B(m)).

Next, an embodiment for producing a dispersion of a magenta pigment by using the integrated fluid mixing apparatus 701 of this embodiment will be described.

As the first reaction liquid, ion-exchanged water is used.

The second reaction liquid is prepared by adding 100 wt. parts of dimethyl sulfoxide to 10 wt. parts of a quinacridone pigment (C.I. Pigment Red 122) and then adding 40 wt. parts of polyoxyethylene lauryl ether as a dispersion agent, followed by addition of a 25 wt. %-potassium hydroxide solution until the mixture is dissolved.

Next, a reaction condition and a reaction process will be described.

Both of temperatures of the first and second reaction liquids are room temperature. The first reaction liquid is jetted from the jet outlet 712 at a flow rate of 50 m/s, and the second reaction liquid is jetted from the jet outlet 713 at a flow rate of 23.3 m/s.

The thus jetted first and second reaction liquids through the jet outlets 712 and 713 intersect each other below the substrate 702 to be mixed. As a result of the mixing of these reaction liquids, the dissolved pigment is precipitated by contact with water which is poor solvent for the pigment. Further, the precipitated pigment is encapsulated by the dispersion agent contained in the second reaction liquid to obtain a pigment dispersion (reaction product) having a pigment concentration of 0.16 wt. %.

An average particle size of the pigment dispersion is measurable by dynamic light scattering photometry. The measured average particle size of the pigment dispersion produced by the above described process is about 40 nm. The average particle size of a commercially available pigment dispersion is about 100 nm with respect to those having a small particle size. Accordingly, according to this embodiment, the integrated fluid mixing apparatus of the present invention can produce smaller particle-size fine particles when compared with a conventional fluid mixing apparatus.

### Embodiment 7

### Integrated Fluid Mixing Apparatus with Lamination Structure

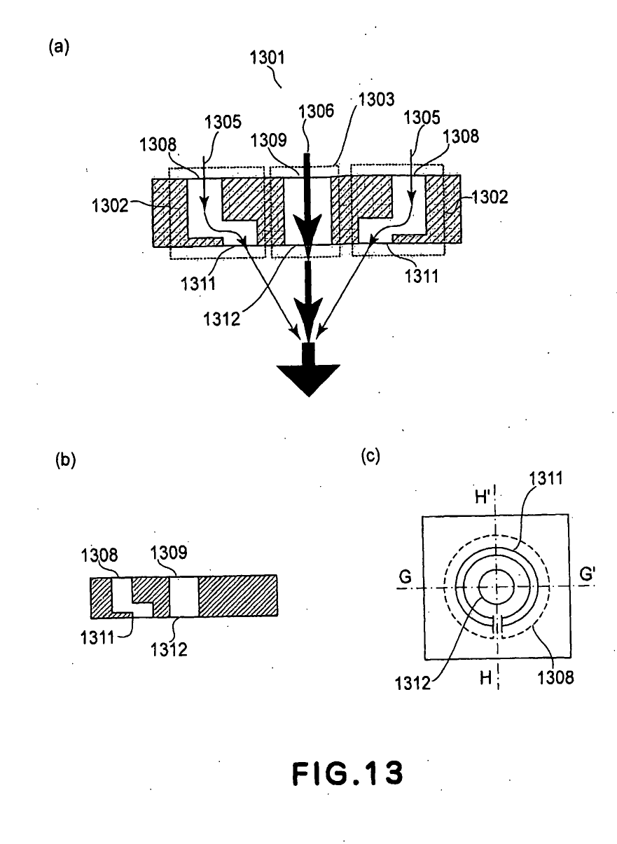

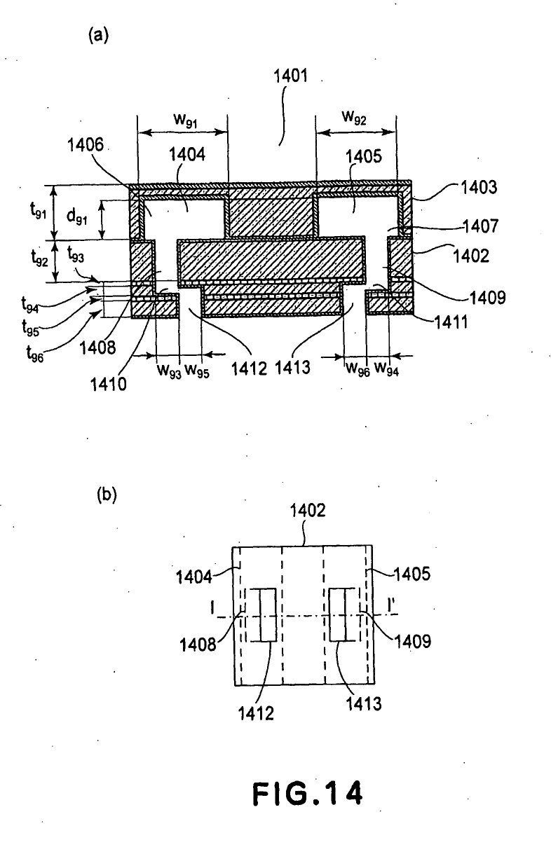

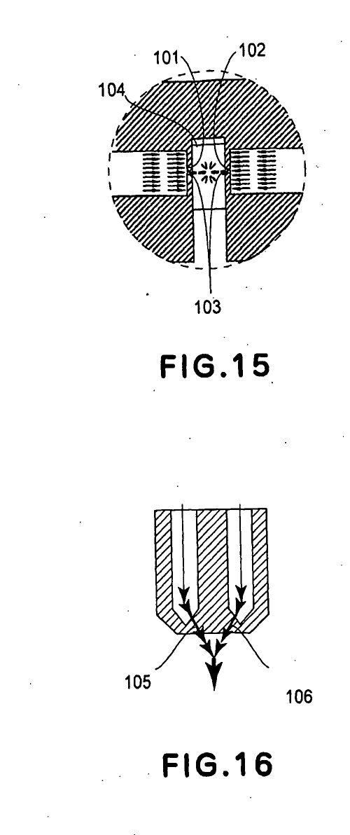

FIGS. 14(a) and 14(b) are schematic views for illustrating an integrated fluid mixing apparatus according to Embodiment 7 of the present invention, wherein FIG. 14(a) is a sectional view of an integrated fluid mixing apparatus 1401 and FIG. 14(b) is a plan view observed from a jet outlet side shown in FIG. 14(a). FIG. 14(a) is the sectional view taken along I-I′ line shown in FIG. 14(b).

The integrated fluid mixing apparatus 1401 includes a substrate 1402 constituting a fluid mixing apparatus according to the present invention and a supply plate 1403 provided with supply flow passageways for supplying two kinds of fluid to the fluid mixing apparatus. The substrate 1402 and the supply plate 1403 are connected to each other.

A manner of mixing fluids in the integrated fluid mixing apparatus will be described with reference to FIG. 14(a). A first reaction liquid (fluid) is introduced from a liquid supply port (not shown) provided to the supply plate 1403 to a supply flow passageway 1404.

The first reaction liquid passes through the supply flow passageway 1404 and an inlet port 1406 to be introduced in a flow passageway 1408. The fluid (first reaction liquid) passed through the flow passageway 1408 is jetted from a jet outlet 1412.

A second reaction liquid (fluid) is introduced in a flow passageway 1409 through a supply flow passageway 1405 and an inlet port 1407 and jetted from a jet outlet 1413. As a result, the first and second reaction liquids (fluids) jetted from the jet outlets 1412 and 1413 intersect each other below the substrate 1402 to be mixed.

Dimensions of the respective portions will be described. The supply plate 1403 has a thickness t91 of 1000 μm. The supply flow passageway 1404 has a width w91 of 500 μm, and the supply flow passageway 1405 has a width w92 of 500 μm. The supply flow passageways 1404 and 1405 have a depth d91 of 800 μm.

The substrate 1402 is a substrate having a lamination structure including a silicon layer, a silicon oxide layer, a silicon layer, a silicon oxide layer, and a silicon layer. More specifically, the substrate 1402 includes a silicon layer having a thickness t96 of 100 μm, a silicon oxide film (layer) having a thickness t95 of 0.5 μm, a silicon layer having a thickness t94 of 50 μm, a silicon oxide film (layer) having a thickness t93 of 0.5 μm, and a silicon layer having a thickness t92 of 200 μm.

The substrate 1402 is provided with the inlet port 1406 having a width w93, the inlet port 1407 having a width w94, the jet outlet 1412 having a width w95, and the jet outlet 1413 having a width w96. The widths w93, w94, w95 and w96 are 250 μm. Further, a height of a connecting portion 1410 is 50 μm equal to that (t94) of the silicon layer.

Peripheral portions of the jet outlets 1412 and 1413 may desirably be subjected to a water/oil repellent treatment. By this treatment, a jet angle of fluid can be stabilized. Further, this treatment for the peripheral portions of the jet outlets 1412 and 1413 is not necessarily required.

In this embodiment, similarly as in Embodiment 1, it is desirable that a recess is provided between the jet outlets 1412 and 1413. As a result, the first reaction liquid adhered to the peripheral portion of the jet outlet 1412 can be prevented from flowing into the jet outlet 1413. Similarly, the second reaction liquid adhered to the peripheral portion of the jet outlet 1413 can be prevented from flowing into the jet outlet 1412. The provision of the recess between the jet outlets 1412 and 1413 is not necessarily required.

In this embodiment, similarly as in Embodiment 2, it is desirable that a plurality of recesses is provided between the jet outlets 1412 and 1413. As a result, the first reaction liquid adhered to the peripheral portion of the jet outlet 1412 can be prevented from flowing into the jet outlet 1413. Similarly, the second reaction liquid adhered to the peripheral portion of the jet outlet 1413 can be prevented from flowing into the jet outlet 1412. The provision of the plurality of recesses between the jet outlets 1412 and 1413 is not necessarily required.

The integrated fluid mixing apparatus of this embodiment can be produced in the same manner as in Embodiment 6.

A jet angle of fluid depends on the height of the connecting portion 1410, so that the connecting portion 1410 requires high processing accuracy. In this embodiment, the height of the connecting portion 1410 is determined by the height t94 of the silicon layer, so that the connecting portion can be processed at high accuracy. This is because the silicon oxide film (layer) having the thickness t95 functions as an etching stopping layer for the inlet ports 1406 and 1407 and thus the depths of the inlet ports 1406 and 1407 are determined by the thicknesses t92 (of the silicon layer), t93 (of the silicon oxide film (layer), and t94 (of the silicon layer)). On the other hand, depths of the jet outlets 1412 and 1413 are determined by the thicknesses t96 (of the silicon layer) and t95 (of the silicon oxide film (layer)). Accordingly, the height of the connecting portion is determined by the thickness t94 of the silicon layer, so that the connecting portion can be processed at high accuracy.

Next, an embodiment for producing a dispersion of a magenta pigment by using the integrated fluid mixing apparatus 1401 of this embodiment will be described.

As the first reaction liquid, ion-exchanged water is used.

The second reaction liquid is prepared by adding 100 wt. parts of dimethyl sulfoxide to 10 wt. parts of a quinacridone pigment (C.I. Pigment Red 122) and then adding 40 wt. parts of polyoxyethylene lauryl ether as a dispersion agent, followed by addition of a 25 wt. %-potassium hydroxide solution until the mixture is dissolved.

Next, a reaction condition and a reaction process will be described.

Both of temperatures of the first and second reaction liquids are room temperature. The first reaction liquid is jetted from the jet outlet 1412 at a flow rate of 10 m/s, and the second reaction liquid is jetted from the jet outlet 1413 at a flow rate of 10 m/s.

The thus jetted first and second reaction liquids through the jet outlets 1412 and 1413 intersect each other below the substrate 1402 to be mixed. As a result of the mixing of these reaction liquids, the dissolved pigment is precipitated by contact with water which is poor solvent for the pigment. Further, the precipitated pigment is encapsulated by the dispersion agent contained in the second reaction liquid to obtain a pigment dispersion (reaction product) having a pigment concentration of 0.16 wt. %.

An average particle size of the pigment dispersion is measurable by dynamic light scattering photometry. The measured average particle size of the pigment dispersion produced by the above described process is about 40 nm. The average particle size of a commercially available pigment dispersion is about 100 nm with respect to those having a small particle size. Accordingly, according to this embodiment, the integrated fluid mixing apparatus of the present invention can produce smaller particle-size fine particles when compared with a conventional fluid mixing apparatus.

### Embodiment 8

### Integrated Fluid Mixing Apparatus with One Linear Fluid Jetting Means and Four Inclined Fluid Jetting Means

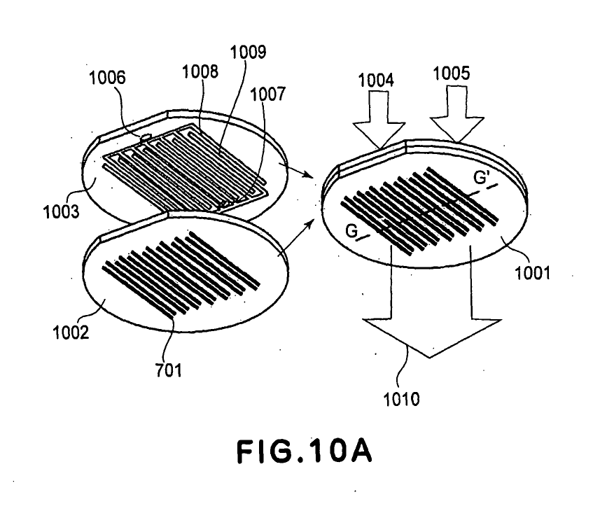

FIGS. 9(a) and 9(b) are schematic views for illustrating an integrated fluid mixing apparatus 901 according to Embodiment 8 of the present invention, wherein FIG. 9(a) is a sectional view of the integrated fluid mixing apparatus 901 and FIG. 9(b) is a plan view observed from a jet outlet side shown in FIG. 9(a). FIG. 9(a) is the sectional view taken along D-D′ line shown in FIG. 9(b).

The integrated fluid mixing apparatus 901 includes a substrate 902 constituting a fluid mixing apparatus and supply plates 903 and 904 provided with supply flow passageways for supplying fluids to the fluid mixing apparatus. The substrate 902 and the supply plates 903 and 904 are connected to each other. The fluid mixing apparatus provided to the substrate 902 includes fine fluid jetting means for jetting reaction liquids (fluids) and the fine fluid jetting means are disposed so that fluid jet directions intersect each other.

The supply plate 903 includes a flow passageway 906 for supplying a second reaction liquid and a flow passageway 907 for passing a first reaction liquid therethrough. The supply plate 904 includes a flow passageway 905 for supplying the first reaction liquid. The substrate 902 includes a fluid jetting means 908 for jetting the first reaction liquid and a fluid jetting means 909 for jetting the second reaction liquid.

Materials and dimensions of these plates and substrate will be described.

The supply plates 903 and 904 are a silicon plate. The supply plate 903 has a thickness t71 of 500 μm, and the supply plate 904 has a thickness t72 of 500 μm.

The supply flow passageway 905 has a width w71 of 2000 μm and a depth d71 of 400 μm. The supply flow passageway 906 has a width w72 of 1700 μm and a depth d72 of 400 μm. The supply flow passageway 907 has a diameter ø71 of 470 μm and a depth of 500 μm.

The substrate 902 is an SOI substrate and includes a silicon layer having a thickness t73 of 25 μm, a silicon oxide film (layer) having a thickness t74 of 0.5 μm, and a support substrate layer having a thickness t75 of 200 μm.

The fluid jetting means 908 has the diameter ø71 of 470 μm. The fluid jetting means 909 includes an inlet port having a width w73 of 100 μm, an inlet port having a width w74 of 100 μm, a jet outlet having a width w85 of 100 μm, and a jet outlet having a width w76 of 100 μm.

Peripheral portions of the jet outlets of the fluid jetting means 909 and 908 may desirably be subjected to a water/oil repellent treatment. By this treatment, a jet angle of fluid can be stabilized. Further, this treatment for the peripheral portions of the jet outlets of the fluid jetting means 909 and 908 is not necessarily required.

In this embodiment, it is desirable that a recess is provided between the jet outlet of the fluid jetting means 909 and the jet outlet of the fluid jetting means 908. As a result, the first reaction liquid adhered to the peripheral portion of the jet outlet of the fluid jetting means 909 can be prevented from flowing into the jet outlet of the fluid jetting means 908. Similarly, the second reaction liquid adhered to the peripheral portion of the jet outlet of the fluid jetting means 908 can be prevented from flowing into the jet outlet of the fluid jetting means 909. The provision of the recess between the jet outlets of the fluid jetting means 909 and 908 is not necessarily required.

In this embodiment, similarly as in Embodiment 2, it is desirable that a plurality of recesses is provided between the jet outlet of the fluid jetting means 909 and the jet outlet of the fluid jetting means 908. As a result, the first reaction liquid adhered to the peripheral portion of the jet outlet of the fluid jetting means 909 can be prevented from flowing into the jet outlet of the fluid jetting means 908. Similarly, the second reaction liquid adhered to the peripheral portion of the jet outlet of the fluid jetting means 908 can be prevented from flowing into the jet outlet of the fluid jetting means 909. The provision of the plurality of recesses between the jet outlets of the fluid jetting means 909 and 908 is not necessarily required.

Next, a production process of the integrated fluid mixing apparatus 901 of this embodiment will be described.

The substrate 902 and the supply plates 903 and 904 are prepared in the same manner as in Embodiment 6 by photolithography and dry etching using plasma of SF₆ gas and C₄F₈ gas.

The substrate 902 and the supply plates 903 and 904 are connected to each other by hot melt bonding.

Next, an embodiment for producing a dispersion of a magenta pigment by using the integrated fluid mixing apparatus 701 of this embodiment will be described.

A first reaction liquid is prepared by adding 100 wt. parts of dimethyl sulfoxide to 10 wt. parts of a quinacridone pigment (C.I. Pigment Red 122) and then adding 40 wt. parts of polyoxyethylene lauryl ether as a dispersion agent, followed by addition of a 25 wt. %-potassium hydroxide solution until the mixture is dissolved.

As a second reaction liquid, ion-exchanged water is used.

The first reaction liquid is jetted in a direction perpendicular to the substrate by the fluid jetting means 908. This is because the first reaction liquid has a smaller surface tension compared with the second reaction liquid, thus being liable to be wettable at the peripheral portion of the jet outlet therefor. If the first reaction liquid is jetted in an inclined direction with respect to the substrate, a jet angle thereof is unstable, so that there is a possibility that the first reaction liquid flows into the jet outlets of the fluid jetting means 909. For this reason, the first reaction liquid is jetted in the direction perpendicular to the substrate.

Next, a reaction condition and a reaction process will be described.

Both of temperatures of the first and second reaction liquids are room temperature. The first reaction liquid is jetted from the flow passageway 908 at a flow rate of 1.4 m/s, and the second reaction liquid is jetted from the flow passageways 909 at a flow rate of 5.8 m/s.

The thus jetted first and second reaction liquids through the fine jet outlets intersect each other below the substrate 902 to be mixed. As a result of the mixing of these reaction liquids, the dissolved pigment is precipitated by contact with water. Further, the precipitated pigment is encapsulated by the dispersion agent contained in the first reaction liquid to obtain a pigment dispersion (reaction product) having a pigment concentration of 0.16 wt. %.

An average particle size of the pigment dispersion is measurable by dynamic light scattering photometry. The measured average particle size of the pigment dispersion produced by the above described process is about 40 nm. The average particle size of a commercially available pigment dispersion is about 100 nm with respect to those having a small particle size. Accordingly, according to this embodiment, the integrated fluid mixing apparatus of the present invention can produce smaller particle-size fine particles when compared with a conventional fluid mixing apparatus.

### Embodiment 9

### Integrated Fluid Mixing Apparatus with Plurality of Fluid Mixing Apparatuses and Supply Flow Passageways

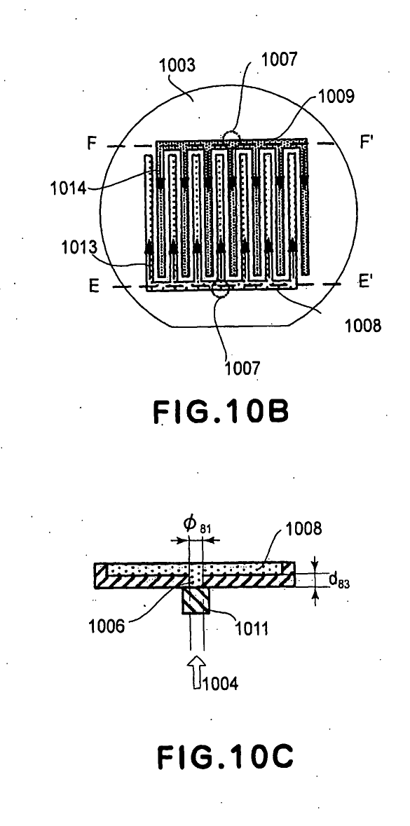

FIG. 10A is a schematic view for illustrating an integrated fluid mixing apparatus 1001 of Embodiment 9. FIG. 10B is a plan view of a supply plate 1003. FIG. 10C is a sectional view taken along E-E′ line shown in FIG. 10B. FIG. 10D is a sectional view taken along F-F′ line shown in FIG. 10B. FIG. 10E is a sectional view taken along G-G′ line shown in FIG. 10A.

The integrated fluid mixing apparatus 1001 will be described with reference to FIG. 10A.

The integrated fluid mixing apparatus 1001 includes a substrate 1002 provided with a plurality of fluid mixing apparatuses 701 described in Embodiment 6 and a supply plate 1003 provided with supply flow passageways 1008 and 1009. The substrate 1002 and the supply plate 1003 are connected to each other.

The substrate 1002 is provided with 250 fluid mixing apparatuses 701.

The supply plate 1003 includes an inlet port (supply port) 1006 for supplying a first reaction liquid 1004 and an inlet port (supply port) 1007 for supplying a second reaction liquid.

Materials and dimensions of these plates and substrate will be described.

The supply plate 1003 is a silicon plate and has a thickness t81 of 1000 μm.

The supply flow passageway 1008 has a width w81 of 500 μm and a depth d81 of 800 μm. The supply flow passageway 1009 has a width w82 of 500 μm and a depth d82 of 800 μm. The supply flow passageway 1006 has a diameter ø81 of 1000 μm and a depth d83 of 200 μm and is connected to the supply flow passageway 1008. Similarly, the supply flow passageway 1007 has a diameter ø82 of 1000 μm and a depth d84 of 200 μm and is connected to the supply flow passageway 1009.

The substrate 1002 is an SOI substrate and includes a silicon layer having a thickness t73 of 25 μm, a silicon oxide film (layer) having a thickness t83 of 0.5 μm, and a support substrate layer having a thickness t84 of 200 μm.

The fluid mixing apparatuses 701 and the same as that described in Embodiment 6 as mentioned above.

Peripheral portions of the jet outlets of the plurality of fluid mixing apparatuses 701 provided to the substrate 1002 may desirably be subjected to a water/oil repellent treatment. By this treatment, a jet angle of fluid can be stabilized. Further, this treatment for the peripheral portions of the jet outlets of the plurality of fluid mixing apparatuses 701 is not necessarily required.

In this embodiment, it is desirable that a recess is provided between the jet outlets of the fluid mixing apparatuses 701. As a result, the first reaction liquid adhered to the peripheral portion of one jet outlet of the fluid mixing apparatus 701 can be prevented from flowing in another direction. Similarly, the second reaction liquid adhered to the peripheral portion of the other jet outlet of the fluid mixing apparatus 701 can be prevented from flowing in another direction. The provision of the recess between the jet outlets of the fluid mixing apparatuses 701 is not necessarily required.

Further, it is desirable that a plurality of recesses is provided between the jet outlets of the fluid mixing apparatuses 701. As a result, the first reaction liquid adhered to the peripheral portion of one jet outlet of the fluid mixing apparatus 701 can be prevented from flowing in another direction. Similarly, the second reaction liquid adhered to the peripheral portion of the other jet outlet of the fluid mixing apparatus 701 can be prevented from flowing in another direction. The provision of the plurality of recesses between the jet outlets of the fluid mixing apparatuses 701 is not necessarily required.

Next, a production process of the integrated fluid mixing apparatus 1001 of this embodiment will be described.

The substrate 1002 and the supply plate 1003 are prepared in the same manner as in Embodiment 6 by photolithography and dry etching using plasma of SF₆ gas and C₄F₈ gas. As a result, it is possible to simultaneously provide the plurality of fluid mixing apparatuses 701 to the substrate 1002. Similarly, it is possible to simultaneously provide the plurality of supply flow passageways 1008 and 1009 to the supply plate 1003.

The substrate 1002 and the supply plate 1003 are connected to each other by hot melt bonding.

Next, a manner of mixing fluids in the integrated fluid mixing apparatus will be described with reference to FIGS. 10A to 10E.

As shown in FIG. 10C, the first reaction is liquid 1004 is introduced from a connector 1011 to the supply port 1006 and is supplied to the supply flow passageway 1008.

Further, as shown in FIG. 10D, the second reaction liquid 1005 is introduced from a connector 1012 to the supply port 1007 and is supplied to the supply flow passageway 1009.

As shown in FIG. 10B, the first reaction liquid 1004 is supplied to the supply flow passageway 1008 which branches off in a plurality of portions. An arrow 1013 shows a flow of the first reaction liquid 1004. Further, the second reaction liquid 1005 is supplied to the supply flow passageway 1009 which branches off in a plurality of portions. An arrow 1014 shows a flow of the second reaction liquid 1005.

Next, as shown in FIG. 10E, the first reaction liquid 1004 is introduced in the fluid mixing apparatuses 701 through the supply flow passageway 1008. Further, the second reaction liquid 1005 is introduced in the fluid mixing apparatuses 701 through the supply flow passageway 1009. The thus supplied first and second reaction liquids 1004 and 1005 intersect each other to be mixed.

As shown in FIG. 10A, the thus mixed product by the respective fluid mixing apparatuses 710 flows in a direction indicated by an arrow 1010.

The integrated fluid mixing apparatus according to this embodiment is particularly effective in the case of improving productivity. This is because the plurality of fluid mixing apparatuses can be prepared simultaneously at high positional accuracy by the combination of photolithography and silicon dry etching. As a result, compared with an ordinary mechanical processing, a processing time can be reduced, thus suppressing an increase in production cost.

### Embodiment 10

### Fluid Mixing System

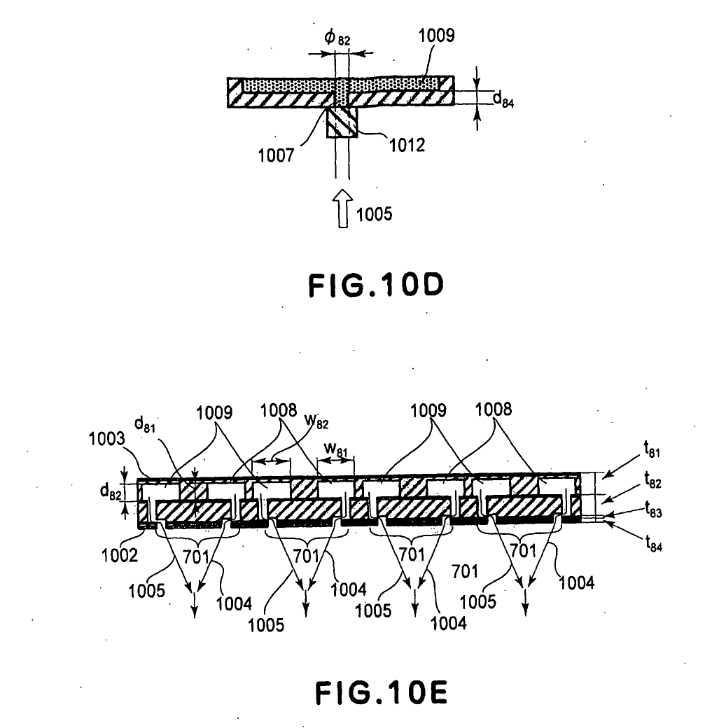

FIG. 11 is a schematic view for illustrating a fluid mixing system 1101 using the above described integrated fluid mixing apparatus according to this embodiment.

Referring to FIG. 11, the fluid mixing system 1101 includes high-pressure gas 1102 for conveying fluid, a regulator 1103 for regulating a conveyance pressure, a first reaction liquid tank (container) 1104 for storing a first reaction liquid, a second reaction liquid tank (container) 1105 for storing a second reaction liquid, a flowmeter 1106 for monitoring an amount of reaction liquid, a heater 1111 and thermometer 1112 for adjusting temperatures of the first reaction liquid and the second reaction liquid, a heater 1113 and thermometer 1114 for controlling a temperature of reaction liquid flowing from an integrated fluid mixing apparatus 1007, a reaction vessel 1008 into which the integrated fluid mixing apparatus 1007 is incorporated, and a collecting tank (container) 1110 for collecting a reaction product.

Next, an embodiment for producing a large amount of a dispersion of a magenta pigment by utilizing the fluid mixing system described above will be explained.

In the first reaction tank 1104, the pigment solution described in Embodiment 6 is stored. Further, in the second reaction tank 1105, ion-exchanged water is stored. The respective reaction liquids are temperature-controlled by the heater 1111 and the thermometer 1112 so as to be kept at a constant temperature of 25° C. Each of the reaction liquids is conveyed to the reaction vessel 1108 by pressure of the high-pressure gas 1102. During the conveyance, an amount of each reaction liquid is controlled by monitoring the flowmeter 1106 and adjusting the regulator 1103.

As a result, the pigment solution (first reaction liquid) is jetted at a flow rate of 23.3 m/s and the ion-exchanged water (second reaction liquid) is jetted at a flow rate of 50 m/s. These first and second reaction liquids intersect each other to be mixed below the integrated fluid mixing apparatus 1107 and in the reaction vessel 1108. An inner temperature of the reaction vessel 1108 is temperature-controlled by the heater 1113 and the thermometer 1114 so as to be constantly kept at 25° C. A reaction product as a result of the mixing of the first and second reaction liquids, i.e., a magenta pigment dispersion 1109 is collected in the collected tank 1110.

According to the fluid mixing system of this embodiment, it is possible to produce the pigment dispersion at a rate of 1650 liters/hour. Further, by temperature-controlling the reaction liquids at the constant temperature, it is possible to reduce a variation in average particle size.

Conventionally, in order to produce a large amount of a mixture substance, by a large-scale production facility, which has been produced through a laboratory-scale production facility, plant design is newly required. For this reason, in order to ensure a reaction reproducibility, much effort and time have been expended. The fluid mixing system according to the present invention can meet a necessary production amount by integration of the fluid mixing apparatuses, so that the effort and time can be considerably reduced.

Further, by disposing a necessary number of integrated fluid mixing apparatuses in the fluid mixing system of the present invention, it is possible to provide a fluid mixing system capable of meeting a necessary production amount.

### INDUSTRIAL APPLICABILITY

As described hereinabove, according to the present invention, it is possible to provide a fluid mixing apparatus capable of obtaining fine particles having a small and uniform particle size. It is also possible to provide a fluid mixing apparatus capable of mixing a plurality of fluids so as to obtain a solid product through reaction of the plurality of fluids.

Further, it is possible to provide an integrated fluid mixing apparatus using the fluid mixing apparatus. It is also possible to provide a fluid mixing system capable of meeting a necessary amount of production by appropriately disposing a necessary number of fluid mixing apparatuses or integrated fluid mixing apparatuses.

While the invention has been described with reference to the structures disclosed herein, it is not confined to the details set forth and this application is intended to cover such modifications or changes as may come within the purpose of the improvements or the scope of the following claims.

1. A fluid mixing apparatus comprising:
a plurality of flow passageways for conveying fluids, respectively; and
jet outlets, corresponding to and communicating with said flow passageways, respectively, for jetting the fluids therefrom so that movement directions of the fluids intersect each other to mix the fluids,
wherein said jet outlets are provided at a surface of a substrate in which said flow passageways are provided, and wherein at least one of said flow passageways communicating with at least one of said jet outlets has a center axis partially shifted from a center axis of at least one of said jet outlets so as to incline a movement direction of a fluid jetted from at least one of said jet outlets with respect to the surface of the substrate.

2. An apparatus according to claim 1, wherein at least one of said flow passageways comprises a first flow passageway and a second flow passageway which are parallel to each other and through which an associated fluid passes to reach an associated jet outlet, and wherein the first flow passageway and the second flow passageway are connected to each other at their side portions located between their center axes.

3. An apparatus according to claim 1, wherein each of said jet outlets is surrounded by a peripheral portion which has been subjected to water-repellent treatment or oil-repellent treatment.

4. An apparatus according to claim 1, wherein the substrate comprises a silicon-containing material and said flow passageways are formed by a semiconductor fine processing.

5. An apparatus according to claim 4, wherein the substrate has a lamination structure comprising layers of silicon, an oxide, silicon, an oxide, and silicon.

6. An apparatus according to claim 2, wherein the first flow passageway and the second flow passageway have chemical resistance.

7. An apparatus according to claim 1, wherein between adjacent jet outlets of said jet outlets, a recess is provided.

8. An apparatus according to claim 1, wherein between adjacent jet outlets of said jet outlets, a plurality of recesses is provided.

9. An apparatus according to claim 1, wherein each of movement directions of two fluids jetted from two jet outlets is inclined with respect to the surface of the substrate to mix the two fluids.

10. An apparatus according to claim 1, wherein one of said flow passageways communicating with an associated jet outlet is a linear flow passageway through which a fluid is jetted in a direction perpendicular to the surface of the substrate.

11. An apparatus according to claim 1, wherein said fluid mixing apparatus further comprises supply flow passageways for supplying the fluids to said flow passageways.

12. An apparatus according to claim 11, wherein said fluid mixing apparatus is configured to mix at least two fluids and comprises a plurality of first jet outlets for jetting a first fluid and a plurality of second jet outlets, corresponding to the plurality of first jet outlets, for jetting a second fluid, and
wherein the first fluid is supplied to the plurality of first jet outlets through a first supply flow passageway, and the second fluid is supplied to the plurality of second jet outlets through a second supply flow passageway.

13. An apparatus according to claim 12, wherein said fluid mixing apparatus further comprises a supply plate provided with the first supply flow passageway and the second supply flow passageway and the substrate is provided with the first jet outlets and the second jet outlets, the substrate and the supply plate being connected to each other.

14. A fluid mixing system comprising:
a fluid mixing apparatus according to claim 12;
supply fluid retaining means for retaining fluid to be supplied to said fluid mixing apparatus;
first temperature control means for controlling a temperature of the fluid to be supplied to said fluid mixing apparatus;
conveying means for conveying the fluid from said supply fluid retaining means to said fluid mixing apparatus;
fluid control means for controlling said conveying means;
second temperature control means for controlling a temperature of the fluid flowing out of said fluid mixing apparatus; and
flow-out fluid retaining means for retaining the fluid flowing out of said fluid mixing apparatus.

15. A process for producing a fluid mixing apparatus including a substrate and at least two fluid jetting means provided to the substrate so that at least two said fluid jetting means are disposed to jet fluids in directions intersecting each other so as to mix the fluids, said process comprising:
a step of forming a first flow passageway by effecting etching from a first surface of the substrate; and
a step of obtaining fluid jetting means by forming a second flow passageway through etching from a second surface of the substrate opposite from the first surface so that the first flow passageway and the second flow passageway have center axes shifted from each other and connecting the first flow passageway and the second flow passageway to each other at their side portions located between their center axes.

16. A process according to claim 15, wherein the substrate comprises a first substrate and a second substrate which are connected to each other.

17. A process according to claim 16, wherein the first substrate and the second substrate comprise different silicon materials.
